(19) United States
(12) Patent Application Publication
(10) Pub. No.: US 2004/0112290 A1
(43) Pub. Date: Jun. 17, 2004

(54) Apparatus for forming film in semiconductor process and method for feeding gas into the same apparatus

(75) Inventors: Jui-Ping Li, Hsinchu (TW); Pei-Feng Sun, Hsinchu (TW); Ching-Cheng Hsieh, Hsinchu (TW); Yang-Nan Liu, Hsinchu (TW)

Correspondence Address: Michael Best & Friedrich LLP, Suite 1900, 401 North Michigan Avenue, Chicago, IL, 60611, US

(73) Assignee: Mosel Vitelic, Inc.

(21) Appl. No.: 10/720,900

(22) Filed: Nov. 24, 2003

Related U.S. Application Data
(62) Division of application No. 09/546,936, filed on Apr. 11, 2000.

(30) Foreign Application Priority Data
Apr. 12, 1999 (TW) 88105800

(51) Int. Cl. C23C 16/00

(52) U.S. Cl. 118/715

(57) ABSTRACT

An apparatus for forming a film on a wafer in the semiconductor process is provided. The apparatus includes an inner part containing a susceptor for mounting thereon the wafer, and an outer part covering the inner part. There are an inlet and an outlet between the inner part and the outer part and gases can flow in and out through them. A special gas-feeding pipe is partially mounted inside the inlet. The gases are ejected from the gas-feeding pipe and toward the outer part instead of the inner part. Hence, the temperature difference between the gases and the inner part is diminished and the film adhered to the inner part will not peel to form particles. It reduces the contamination problem. A gas-feeding method is also provided according to the present apparatus. The method includes steps: (a) feeding the gases through the gas-feeding pipe so that the gases are ejected toward the outer part instead of the inner part, and (b) leading the gases into the inner part along a path between the outer part and the inner part. It reduces the contamination problem because the low-temperature gases will not approach the inner part before they approach the outer part.

### FIELD OF THE INVENTION

The present invention relates to an apparatus for forming a film on a wafer and a gas-feeding method relative to the apparatus, and more particularly to an apparatus for forming a film on a wafer and a gas-feeding method relative to the apparatus without contamination problem.

### BACKGROUND OF THE INVENTION

Chemical vapor deposition (CVD) process is a usual method for forming a film on a wafer. It employs chemical reactions by reacting gaseous reactants in the chamber to form solid products. Then, the solid products are deposited on the wafer to form the film. Compared with the film formed by other methods, the film formed by chemical vapor deposition process has better crystalline property, stoichiometry, and step coverage effect. Hence, chemical vapor deposition process is a prior and major method to form a film made of any materials, e.g. conductive materials, semiconductive materials, and dielectric materials.

The temperature required to execute chemical vapor deposition process is much higher than room temperature in order to provide enough activation energy to proceed chemical reactions. The reaction temperature is usually ranged from 400° C. to 850° C. Hence, the great temperature difference between the interior and the exterior of the chamber will cause serious problem and should not be ignored. Please refer to FIG. 1(A) which is a schematic diagram showing a typical chemical vapor deposition reactor 1. The reactor 1 mainly includes an outer tube 11 and an inner tube 12. There is a susceptor 2 in the inner tube 12. At least one wafer 21 is mounted on the susceptor 2. After the chemical vapor deposition process, a film is formed on the wafer 21. The following example is given to show how to deposit a silicon nitride film on wafers. Silicon nitride is often formed by reacting dichlorosilane with ammonia by the following equation:

3SiH₂Cl_{2(g)}+7NH_{3(g)}→Si₃N₄₍ₛ₎+3NH₄Cl₍ₛ₎+3HCl_{(g)}+6H_{2(g)}

The required temperature is about 700° C. to 800° C. and the requited pressure is about 0.1 torr to 1 torr. This method is called “low pressure chemical vapor deposition (LPCVD)” due to its low-pressure range. Therefore, a heater 3 should be provided to heat the inner tube 12 so that the interior of the inner tube 12 can approach the proper temperature for proceeding reactions. At the same time, excess gases must be exhausted through the outlet 41 to keep the low pressure in the inner tube 12.

After the silicon nitride film is grown, the wafer 21 should be unloaded. Before the unload step, a great amount of nitrogen (room temperature) is fed through the gas-feeding pipe 5 partially inserted in the inlet 42 for 10 min to 15 min, timing depend on flow rate, to purge the camber. This step can devacuum the chamber and reduce the inner temperature, Then, the wafer 21 is taken out and new wafers are loaded. Chemical vapor deposition process, however, not only deposits the silicon nitride film on the wafer 21, but also deposits a layer of silicon-nitrogen compound (SiₓN₄) film 6 on the interior wall of the inner tube 12 and outer tube 11. Please refer to FIG. 1(B) which is a schematic diagram showing an enlargement of a portion of FIG. 1(A). It is known that the inner tube 12 must be cleaned every several cycles to prevent the SiₓN₄ compounds from contaminating the wafer 21. It must be noticed that outer tube 11 and an inner tube 12. There is a susceptor 2 in the inner tube 12 At least one wafer 21 is mounted on the susceptor 2. After the chemical vapor deposition process, a film is formed on the wafer 21. The following example is given to show how to deposit a silicon nitride film on wafers. Silicon nitride is often formed by reacting dichlorosilane with ammonia by the following equation:

3SiH₂Cl_{2(g)}+7NH_{3(g)}→Si₃N₄₍ₛ₎+3NH₄Cl₍ₛ₎+3HCl_{(g)}+6H_{2(g)}

The required temperature is about 700° C. to 800° C. and the requited pressure is about 0.1 torr to 1 torr. This method is called “low pressure chemical vapor deposition (LPCVD)” due to its low-pressure range. Therefore, a heater 3 should be provided to heat the inner tube 12 so that the interior of the inner tube 12 can approach the proper temperature for proceeding reactions. At the same time, excess gases must be exhausted through the outlet 41 to keep the low pressure in the inner tube 12.

After the silicon nitride film is grown, the wafer 21 should be unloaded. Before the unload step, a great amount of nitrogen (room temperature) is fed through the gas-feeding pipe 5 partially inserted in the inlet 42 for 10 min to 15 min, timing depend on flow rate, to purge the camber. This step can devacuum the chamber and reduce the inner temperature. Then, the wafer 21 is taken out and new wafers are loaded. Chemical vapor deposition process, however, not only deposits the silicon nitride film on the wafer 21 but also deposits a layer of silicon-nitrogen compound (SiₓN₄) film 6 on the interior wall of the inner tube 12 and outer tube 11 Please refer to FIG. 1(B) which is a schematic diagram showing an enlargement of a portion of FIG. 1(A) It is known that the inner tube 12 must be cleaned every several cycles to prevent the Si_{%}N₄ compounds from contaminating the wafer 21. It must be noticed that when the great amount of low temperature nitrogen meets the inner tube 12, there is a great temperature difference ranged from 600° C. to 700° C. between the inner tube 12 and outer tube 11. At the moment, great heat stress is applied to the thin film 6 adhered to the inner tube 6. Hence, the thin film 6 peels off the inner tube 12 and outer tube 11 and forms particles 61 to contaminate the wafer 21 or the products. Such condition seriously affects the product quality and the plant capacity.

There are two methods used now for solving the contamination problem caused by the instant temperature difference. One is to rise the temperature of the nitrogen before it is fed so that the temperature difference between two sides of the inner tube 12 can be decreased. It is apparent that such method will waste much heat cost. The other one is to restrict the flow rate of the fed nitrogen to the range between 300 sccm to 500 sccm to purge the chamber. It often spends more than 30 min to purge it. It is apparent that this method is disadvantage to the mass production. Hence, a better method for solving the contamination problem without increasing the cost and the production time must be developed to increase the competition power.

### SUMMARY OF THE INVENTION

An objective of the present invention is to disclose both an apparatus for forming a film and a gas-feeding device. These apparatus and device can reduce the contamination sources without increasing the heat cost and the production time.

Another objective of the present invention is to disclose a method for feeding gases into a film-forming apparatus to form films. This method can reduce the contamination sources without increasing the heat cost and the production time.

In accordance with the present invention, the apparatus includes an inner part, an outer part, and a gas-feeding pipe. The outer part covers the inner part and a gas inlet and a gas outlet are formed between the inner part and the outer part. The gas-feeding pipe is partially located inside the gas inlet and its special structure can control the feeding gases to flow in the direction toward the outer part instead of the inner part so that the film adhered to the inner part will not peel off.

In accordance with another aspect of the present invention, the inner part is a chamber if the apparatus is used in chemical vapor deposition process. Certainly, the apparatus can be used in physical vapor deposition process. Preferably, the inner part, the outer part, and the gas-feeding pipe are made of quartz or SiC to resist higher temperature and stree between Si₃N₄ film and SiC or quartz.

In accordance with another aspect of the present invention, the gas-feeding pipe must have special structures. For example, the gas-feeding pipe has several holes formed on one side near the outer part to make the feeding gases flow in the direction toward the outer tube 11. Certainly, the holes may be gradient holes; that is, the holes near the end of the gas-feeding pipe have smaller diameters. Preferably, the portion of the gas-feeding pipe mounted inside the gas inlet has a length shorter than 70 cm or two-thirds of the length of the inner part to prevent the particles. Another example is given that the gas-feeding pipe has an exit with a specific direction inclined to the outer part to make the feeding gases flow in the direction toward the outer part.

In accordance with another aspect of the present invention, the apparatus further includes a flow controller, a heating device, and a pumping device The flow controller can control the flow rate of the feeding gases in the range of 300 sccm to 2000 sccm. The heating device can control the reaction temperature of the semiconductor process in the range of 600° C. to 850° C. The pumping device can control the reaction pressure of the semiconductor process in the range of 0.1 torr to 1 torr

In accordance with the present invention, the gas-feeding device includes a gas-feeding pipe and a flow controller. The gas-feeding pipe is partially located inside the gas inlet and its special structure can control the feeding bases to flow in the direction toward the outer part instead of the inner part. Hence, the particles adhered to the inner part will not peel off due to great temperature difference. The flow controller is used for controlling the flow rate of the feeding gases. The gas-feeding device is applicable to the case when the temperature difference between the feeding gases and the inner part is about 300° C. to 850° C.

In accordance with the present invention, by way of making reference to the foregoing paragraphs, the method includes steps of: (a) feeding gases in the direction toward the outer part instead of the inner part to prevent the particles adhered to the inner tube, boat or production from peeling off, and (b) leading the gas into the inner part along a path between the outer part and the inner part.

In accordance with another aspect of the present invention, the films are silicon nitride films and the particles are SiₓN₄ compounds.

In accordance with another aspect of the present invention, the chemical vapor deposition process includes steps of: (c) controlling the temperature in the inner part of the film-forming apparatus in the range of 600° C. to 850° C.; and (d) controlling the pressure in the inner part of the film-forming apparatus in the range of 0.1 torr to 1 torr.

In accordance with another aspect of the present invention, the gases are purge gases or reaction gases. Preferably, purge gases are nitrogen, argon, or other inert gases.

In accordance with another aspect of the present invention, after the films are formed, the semiconductor process further includes a step of (e) controlling the flow rate of the feeding gases in the range of 300 sccm to 2000 sccm for 5 min to 15 min to devacuum the film-forming apparatus.

The present invention may best be understood through the following description with reference to the accompanying drawings, in which:

### BRIEF DESCRIPTION OF THE DRAWINGS

FIG. 1(A) is a schematic diagram showing the conventional chemical vapor deposition reactor;

FIG. 1(B) is a schematic diagram showing an enlargement of the gas-feeding pipe of FIG. 1(A); and

FIGS. 2(A)-(C) are schematic diagrams showing three preferred embodiments of the gas-feeding devices according to the present invention.

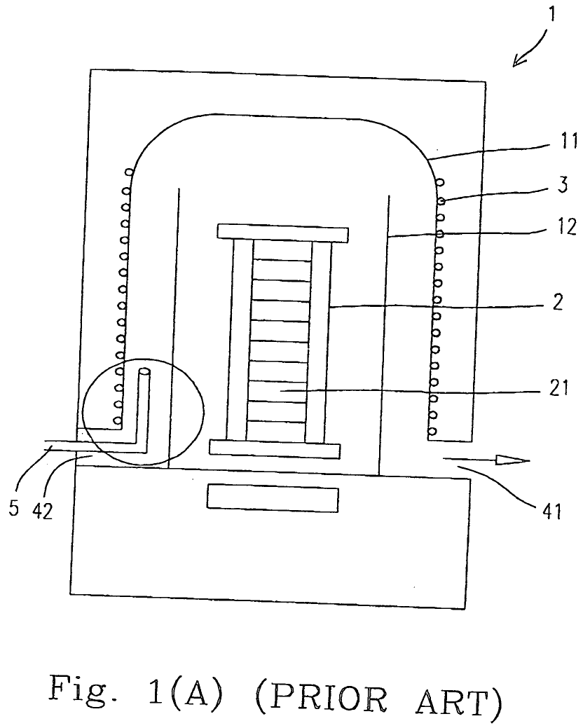

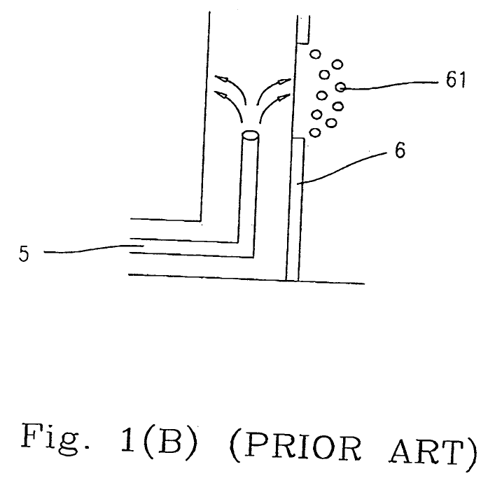

### DETAILED DESCRIPTION OF THE PREFERRED EMBODIMENT

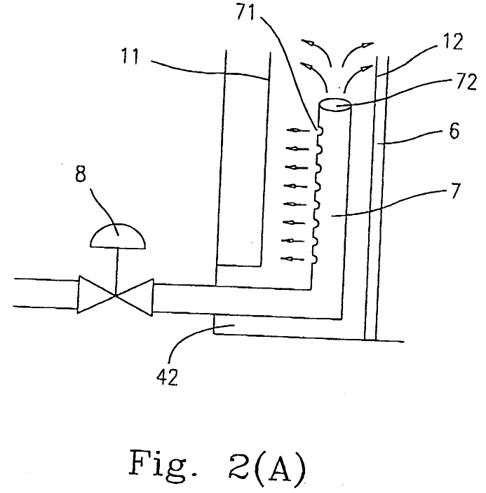

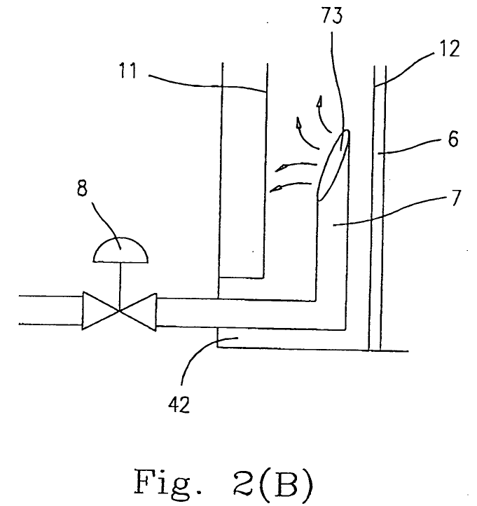

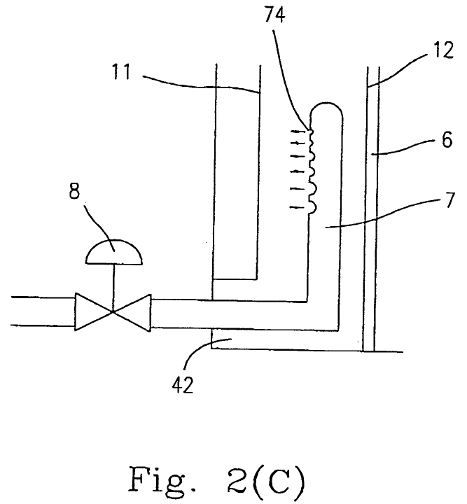

Please refer to FIG. 2(A) which is a schematic diagram showing a preferred embodiment of a gas-feeding device according to the present invention. A portion of the gas-feeding pipe 7 is inserted in the gas inlet 42 formed between the outer tube (part) 11 and the inner tube (part) 12. There are one row or few rows of holes 71 formed on the gas-feeding pipe 7. The holes 71 are formed near the outer tube 11 instead of the inner tube 12. The length of the inserted portion of the gas-feeding pipe 7 is shorter than 70 cm for a chemical vapor deposition reactor with common size. If a chemical vapor deposition reactor has a special size, the length of the inserted portion should be shorter than two-thirds of the length of the inner tube 12.

In the above-mentioned gas-feeding step, when a great amount of the nitrogen is fed into the chemical vapor deposition reactor, the major portion of the nitrogen is ejected toward the outer tube 11 through the holes 71, and only the minor portion is ejected toward both the outer tube 11 and the inner tube 12 through the exit 72. It is different from the traditional gas-feeding pipe described in the foregoing paragraphs. The temperature of the nitrogen will rise in some degree before it approaches the inner tube 12 because of the higher temperature in the chemical vapor deposition reactor. Therefore, the temperature difference between the fed nitrogen and the inner tube 12 to diminish the heat stress applied to the films 6. The SiₓN₄ films 6 will not peel from the inner tube 12 as easily as before. It is noted that no additional heat cost is required to reduce the temperature difference, but the contamination problem can be solved. It is also noted that the nitrogen can be fed by the flow rate ranged from 300 sccm to 2000 sccm faster than before. Therefore, the time required to devacuum the chemical vapor deposition reactor is shortened, that is, the production time is shortened.

Please refer to FIG. 2(B) which is a schematic diagram showing a second preferred embodiment of a gas-feeding device according to the present invention. The exit 73 of the gas-feeding pipe 7 has a special inclined direction different from the prior art. The normal vector of the exit 73 points to the outer tube 11 rather than parallel the outer tube 11. The length of the inserted portion of the gas-feeding pipe 7 is shorter than 70 cm for a chemical vapor deposition reactor with common size. If a chemical vapor deposition reactor has a special size, the length of the inserted portion should be shorter than two-thirds of the length of the inner tube 12.

In the gas-feeding step, the great amount of the nitrogen is ejected toward the outer tube 11 through the oblique exit 73. Then the nitrogen flows along the path between the outer tube 11 and the inner tube 12 to enter the inner tube 12. The nitrogen will approach the outer tube 11 for a while and there is heat flux flowing from the outer tube 11 to the nitrogen before it approaches the inner tube 12 because the outer tube 11 has lighter temperature. Therefore, the temperature difference between the fed nitrogen and the inner tube 12 decreases to diminish the heat stress applied to the films 6. The SiₓN₄ films 6 will not peel from the inner tube 12 as easily as before. It is noted that no additional heat cost is required to reduce the temperature difference, but the contamination problem can be solved. It is also noted that the nitrogen can be fed by the flow rate ranged from 300 sccm to 1500 sccm faster than before. Therefore, the time required to devacuum the chemical vapor deposition reactor is shortened, that is, the production time cycle is shortened.

Please refer to FIG. 2(C) which is a schematic diagram showing a third preferred embodiment of a gas-feeding device according to the present invention. The gas-feeding pipe does not have exits, while there are one row or few rows of gradient holes 74 formed on the gas-feeding pipe 7. The so called “gradient holes” means that the holes 74 have smaller diameters near the end of the gas-feeding pipe 7. The length of the inserted portion of the gas-feeding pipe 7 except the region having the gradient holes 74 is shorter than 70 cm for a chemical vapor deposition reactor with common size. If a chemical vapor deposition reactor has a special size, the length should be shorter than two-thirds of the length of the inner tube 12.

In the gas-feeding step, when a great amount of the nitrogen is fed into the chemical vapor deposition reactor, all the nitrogen is ejected toward the outer tube 11 through the gradient holes 74. The temperature of the nitrogen will rise in some degree when heat flux flows from the outer tube 11 to the nitrogen before it approaches the inner tube 12 The larger holes eject the major portion of the nitrogen; that is, the major portion of the nitrogen will flow along the outer tube 11 for a longer distance than the minor portion will, so the fed nitrogen is heated homogeneously. The temperature difference between the fed nitrogen and the inner tube 12 decreases to diminish the heat stress applied to the films 6. The SiₓN₄ films 6 will not peel from the inner tube 12 as easily as before. It is noted that no additional heat cost is required to reduce the temperature difference, but the contamination problem can be solved. It is also noted that the nitrogen can be fed by the flow rate (controlled by the flow controller 8) ranged from 300 sccm to 2000 sccm faster than before. Therefore, the time required to devacuum the chemical vapor deposition reactor is shortened, that is, the process cycle is shortened.

A gas-feeding method is also developed according to the present invention. In brief, the method includes two steps: (a) feeding the gases into the as inlet between the outer tube and the inner tube to make all the gases or portions of the gases ejected toward the outer tube instead of the inner tube to prevent the particles adhered to the inner tube from peeling off; and (b) leading the ejected gases into the inner tube along a path between the outer part and the inner part. The conventional gas-feeding pipe must be improved to execute these two steps. There are three preferred embodiments provided in the foregoing paragraphs. For example, one row or few rows of uniform holes or gradient holes are formed on the gas-feeding pipe near the outer tube. Changing the direction of the exit of the gas-feeding pipe is another example. Therefore, portions of the feeding gases are heated in some degree by the outer tube before they reach the inner tube. The contamination problem can thus be solved Without increasing the purge time and the heat cost.

A chemical vapor deposition apparatus is also disclosed according to the present invention. The apparatus includes an outer part 11, an inner part 12, and a gas-feeding pipe 7 with special structure. The inner part 12, the outer part 11, and the gas-feeding pipe 7 are made of quartz or SiC to resist high reaction temperature ranged from 400° C. to 850° C. and stress issue. The outer part 11 covers the inner part 12. A gas inlet 42 and a gas outlet 41 are formed between the inner part 12 and the outer part 11 so that gases can flow in/out through them. Three preferred embodiments of the gas-feeding pipe 7 with special structure are already shown in FIG. 2 and described in detail. In addition to the above-mentioned device, the apparatus further includes a heating device 3, a pumping device (not shown), and a flow controller 8. The heating device 3 can heat the susceptor 2, wafers 21, or reaction gases in the inner part 12 to control the reaction temperature. For instance, the proper reaction temperature to form silicon nitride films ranges from 600° C. to 850° C. The pumping device connects with the gas outlet 41 of the apparatus to exhaust the gases in the apparatus and keep the reaction pressure in the inner part 12. For instance, the proper reaction pressure to form silicon nitride films ranges from 0.1 torr to 1 torr. The flow controller 8 is used to control the flow rate of the feeding gases. Too fast flow rate worsens the contamination problem and causes turbulent flow, while too slow flow rate increases the process time. Typically, the proper flow rate ranges from 300 sccm to 2000 sccm on condition that the purge time ranges from 5 min to 15 min.

Of course the preferred embodiments recited in the specification are used to describe the characteristics of the present invention, but the present invention is not limited to the recited preferred embodiments. The gas-feeding device and gas-feeding method can be applied to not only chemical vapor deposition process but also physical vapor deposition process. Besides, the present invention covers not only three types of gas-feeding pipes shown in the specification. The gas-feeding pipes capable of directing the feeding gases to the outer part are also involved in the present invention, e.g. gas-feeding pipe with a bent structure. Also, the silicon nitride films are not the only products of the present invention. Many materials including conductive materials, semiconductive materials, and dielectric materials can be formed according to the present invention. Moreover, the feeding gases can be purge gases (nitrogen, argon, or other inert gases) or reaction gases if the temperature difference between the feeding gases and the inner tube plays a disadvantageous role in the process.

While the invention has been described in terms of what are presently considered to be the most practical and preferred embodiments, it is to be understood that the invention need not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An apparatus for forming a film on a wafer in a semiconductor process comprising:
an inner part for mounting therein said wafer;
an outer part covering said inner part wherein a gas inlet and a gas outlet are formed between said inner part and said outer part; and
a gas-feeding pipe partially mounted inside said gas inlet for adjusting a feeding gas flowing therein in the direction toward said outer part instead of said inner part to prevent particles adhered to said inner part from peeling off.

2. The apparatus according to claim 1 wherein said inner part is a chamber when said semiconductor process is a chemical vapor deposition process.

3. The apparatus according to claim 1 wherein said inner part, said ouster part, and said gas-feeding pipe are made of quartz.

4. The apparatus according to claim 1 wherein said inner part, said outer part, and said as-feeding pipe are made of SiC.

5. The apparatus according to claim 1 wherein said gas-feeding pipe having thereon a plurality of holes on one side near said outer part for passing through said feeding gas.

6. The apparatus according to claim 5 wherein said plurality of holes are gradient holes.

7. The apparatus according to claim 1 wherein a portion of said gas-feeding pipe mounted inside said gas inlet has a length shorter than 70 cm.

8. The apparatus according to claim 1 wherein a portion of said gas-feeding pipe mounted inside said gas inlet has a length shorter than two-thirds of the length of said inner part.

9. The apparatus according to claim 1 wherein said gas-feeding pipe having an exit with a specific direction toward said outer part.

10. The apparatus according to claim 1 wherein said apparatus further includes:
a flow controller mounted to said gas-feeding pipe for controlling a flow rate of said feeding gas in the range of 300 sccm to
2000 sccm;
a heating device for controlling the reaction temperature of said semiconductor process in the range of 400° C. to 850° C.; and
a pumping device for controlling the pressure in said inner part in the range of 0.1 torr to 1 torr.

11. The apparatus according to claim 10 wherein the temperature different between said feeding gas and said inner part is between 600° C. to 850° C.

12. A gas-feeding device for feeding a gas into a film-forming apparatus having an inner part and an outer part to form a film on a wafer mounted in said inner part, the temperature difference between said gas and said inner part being ranged from 300°C. to 850° C., comprising:
a gas-feeding pipe partially mounted between said inner part and said outer part for adjusting said gas flowing therein in the direction toward said outer part to prevent particles adhered to said inner part from peeling off, and
a flow controller connected to said gas-feeding pipe for controlling a flow rate of said gas.

13. Tie gas-feeding device according to claim 12 wherein said gas-feeding pipe has a length shorter than 70 cm.

14. The gas-feeding device according to claim 12 wherein said gas-feeding pipe having thereon a plurality of holes on one side near said outer part for passing through said gas.

15. The gas-feeding device according to claim 14 wherein said plurality of holes are gradient holes.

16. The gas-feeding device according to claim 12 wherein said gas-feeding pipe having an exit with a specific direction toward said outer part.

17. Tie gas-feeding device according to claim 12 wherein said flow controller controls said flow rate of said gas in the range of 300 sccm to 2000 sccm.

18. A method for feeding a gas into a film-forming apparatus having an inner part and an outer part to form a film on a wafer mounted in said inner part in a semiconductor process, comprising steps of:
(a) feeding said gas into a space between said outer part and said inner part and in the direction toward said outer part to prevent particles adhered to said inner part from peeling off; and
(b) leading said gas into said inner part along a path between said outer part and said inner part.

19. The method according to claim 18 wherein said semiconductor process is one of chemical vapor deposition process and physical vapor deposition process.

20. The method according to claim 19 wherein said film is a silicon nitride film and said particles are SiₓN₄ compounds.

21. The method according to claim 20 wherein said process includes steps of:
(c) controlling the temperature in said inner part of said film-forming apparatus in the range of 600° C. to 850° C.; and
(d) controlling the pressure in said inner part of said film-forming apparatus in the range of 0.1 torr to 1 torr.

22. The method according to claim 20 wherein said gas is a purge gas selected from a group consisting of nitrogen, argon, and other inert gases.

23. The method according to claim 22 wherein after said film is formed, said process further includes a step of (e) controlling the flow rate of said gas in the range of 300 sccm to 2000 sccm for 5 min to 15 min to devacuum said film-forming apparatus.
